(19) United States
(12) Patent Application Publication
(10) Pub. No.: US 2007/0196938 A1
(43) Pub. Date: Aug. 23, 2007

(54) Nitride semiconductor device and method for fabricating the same

(76) Inventor: Masahiro Ogawa, Osaka (JP)

Correspondence Address: MCDERMOTT WILL & EMERY LLP, 600 13TH STREET, N.W., WASHINGTON, DC, 20005-3096, US

(21) Appl. No.: 11/594,915

(22) Filed: Nov. 9, 2006

(30) Foreign Application Priority Data
Feb. 20, 2006 (JP) 2006-043007

(51) Int. Cl. H01L 21/00

(52) U.S. Cl. 438/22; 438/46

(57) ABSTRACT

A nitride semiconductor device includes: a first nitride semiconductor whose surface is etched; and a second nitride semiconductor formed on the etched surface of the first nitride semiconductor. Of oxygen, carbon, and silicon contained in the interface between the first and second nitride semiconductors, at least silicon has a concentration equal to or less than one tenth the dopant concentration in the first nitride semiconductor.

### CROSS-REFERENCE TO RELATED APPLICATIONS

This application claims priority under 35 U.S.C. §119 on Patent Application No. 2006-43007 filed in Japan on Feb. 20, 2006, the entire contents of which are hereby incorporated by reference.

### BACKGROUND OF THE INVENTION

(a) Fields of the Invention

The present invention relates to nitride semiconductor devices such as semiconductor laser elements or light emitting diode elements and to their fabrication methods.

(b) Description of Related Art

Group III-V nitride semiconductors (referred hereinafter to as nitride semiconductors) whose general formulas are represented by AlₓGa_{y}In_{1-x-y}N (where x and y satisfy 0≦x≦1, 0≦y≦1, and 0≦x+y≦1) are compound semiconductor materials capable of emitting light ranging from ultra-violet region through infra-red region, and thus they hold the promise of being applied to light emitting devices and light receiving devices.

For example, when a laser element using a nitride semiconductor is fabricated, etching is needed in forming an electrode and a waveguide which generates a laser oscillation. The etching performed in this process includes a dry etching method using a reactive gas and a wet etching method using an alkaline aqueous solution, such as an aqueous solution of potassium hydroxide, with ultraviolet light radiated.

When etching by the conventional etching method described above is performed on a nitride semiconductor, however, the etched surface of the nitride semiconductor is damaged by the etching. Also, in the etched surface of the nitride semiconductor, the concentration of impurities such as oxygen (0), carbon (C), silicon (Si), and the like is increased. A layer having a high concentration of these impurities (referred hereinafter to as a deteriorated layer) often exhibits n-type conductivity. For example, in the case where a p-type nitride semiconductor is etched, if the deteriorated layer created by impurities in the surface thereof exhibits n-type conductivity, an np junction is produced. This causes the problem that a current becomes difficult to pass. In addition, the deteriorated layer may cause new crystal defects.

### SUMMARY OF THE INVENTION

In view of the conventional problems mentioned above, an object of the present invention is to provide a nitride semiconductor device in which after etching, the surface of an etched nitride semiconductor becomes clean and no deteriorated layer is created in the surface.

To accomplish the above object, a nitride semiconductor device according to the present invention is designed so that in an etched surface of a nitride semiconductor, the concentration of impurities composed of oxygen, carbon, or silicon is made lower than the concentration of a dopant added to the nitride semiconductor.

To be more specific, a nitride semiconductor device according to the present invention is characterized in that the device includes: a first nitride semiconductor whose surface is etched; and a second nitride semiconductor formed on the etched surface of the first nitride semiconductor, and of oxygen, carbon, and silicon contained in the interface between the first and second nitride semiconductors, at least silicon has a concentration equal to or less than one tenth the dopant concentration in the first nitride semiconductor.

With the nitride semiconductor device of the present invention, a deteriorated layer induced by impurities such as silicon is difficult to create in the etched surface of the first nitride semiconductor. Therefore, losses produced by the deteriorated layer in injecting an operating current into the semiconductor device can be reduced to further improve device characteristics.

Preferably, in the nitride semiconductor device of the present invention, the first nitride semiconductor is a p-type nitride semiconductor.

Preferably, in the nitride semiconductor device of the present invention, the second nitride semiconductor is a p-type nitride semiconductor.

Preferably, the nitride semiconductor device of the present invention further includes: a first optical guide layer of a first conductivity type; an active layer; a second optical guide layer of a second conductivity type; and a cladding layer of the second conductivity type, which are each made of a nitride semiconductor and sequentially formed on a substrate, and the first nitride semiconductor is the second optical guide layer, and the second nitride semiconductor is the cladding layer.

Preferably, in the above case, the nitride semiconductor device of the present invention further includes a current blocking layer formed between the second optical guide layer and the cladding layer, having an opening exposing the second optical guide layer, and made of a nitride semiconductor of the first conductivity type.

A method for fabricating a nitride semiconductor device according to the present invention is characterized in that the method includes: the step (a) of etching a first nitride semiconductor; the step (b) of removing impurities in the etched surface of the first nitride semiconductor; and the step (c) of forming a second nitride semiconductor on the etched surface of the first nitride semiconductor.

With the method for fabricating a nitride semiconductor device according to the present invention, impurities contained in the etched surface of the first nitride semiconductor are removed and then the second nitride semiconductor is formed on the etched surface of the first nitride semiconductor. Therefore, an impurity-induced deteriorated layer is removed which is formed in an exposed surface of the etched first nitride semiconductor. Thus, after the deteriorated layer is removed, the second nitride semiconductor is formed on the resulting first nitride semiconductor. This reduces losses produced by the deteriorated layer at the interface between the first and second nitride semiconductors, so that a nitride semiconductor device with good device characteristics can be provided.

Preferably, the method for fabricating a nitride semiconductor device according to the present invention further includes: after the step (b) and before the step (c), the step (d) of subjecting the etched surface of the first nitride semiconductor to heat treatment. With this method, the flatness of the etched surface of the first nitride semiconductor is improved to enhance the crystallinity of the second nitride semiconductor formed on the etched surface.

Preferably, in the above case, in the step (d), the heat treatment is performed in an atmosphere containing nitrogen radicals.

Preferably, in the method for fabricating a nitride semiconductor device according to the present invention, in the step (b), the impurities are removed at a higher temperature than a temperature at which the second nitride semiconductor is formed in the step (c).

Preferably, in the method for fabricating a nitride semiconductor device according to the present invention, in the step (b), the impurities are removed by etching with a gas containing at least hydrogen.

Preferably, in the method for fabricating a nitride semiconductor device according to the present invention, in the step (b), the impurities are removed by etching with a gas containing at least hydrogen chloride.

Preferably, in the method for fabricating a nitride semiconductor device according to the present invention, of oxygen, carbon, and silicon, at least silicon constitutes the impurities.

Preferably, in the method for fabricating a nitride semiconductor device according to the present invention, the first and second nitride semiconductors are p-type nitride semiconductors.

Preferably, the method for fabricating a nitride semiconductor device according to the present invention further includes: the step (e) of sequentially forming, on a substrate, a first cladding layer of a first conductivity type, a first optical guide layer of the first conductivity type, an active layer, a second optical guide layer of a second conductivity type as the first nitride semiconductor, and a current blocking layer of the first conductivity type, which are each made of a nitride semiconductor; the step (f) of forming, by etching, an opening through the current blocking layer, the opening exposing the second optical guide layer; and the step (g) of forming a second cladding layer of the second conductivity type on the current blocking layer with the opening formed therethrough and on a portion of the second optical guide layer exposed from the opening, the second cladding layer serving as the second nitride semiconductor, the step (b) is the step of removing impurities in the etched surface of the second optical guide layer, and the step (c) is the step of forming the second cladding layer on the etched surface of the second optical guide layer.

### BRIEF DESCRIPTION OF THE DRAWINGS

FIG. 1 is a sectional view schematically showing a semiconductor laser element which is a nitride semiconductor device according to one embodiment of the present invention.

FIG. 2 is a graph showing the relation between the peak concentration of oxygen, carbon, and silicon in the interface between a p-type optical guide layer and a p-type cladding layer and the operating voltage in the semiconductor laser element according to one embodiment of the present invention.

FIG. 3 is a graph showing the relation between the peak concentration of oxygen, carbon, and silicon in the interface between the p-type optical guide layer and the p-type cladding layer and the Mg concentration in the p-type optical guide layer in the semiconductor laser element according to one embodiment of the present invention.

FIGS. 4A to 4E are sectional views showing a method for fabricating a semiconductor laser element according to one embodiment of the present invention in the order of its fabrication process steps.

FIG. 5 is a graph showing the impurity concentrations of magnesium, oxygen, carbon, and silicon in the interface between the p-type optical guide layer and the p-type cladding layer in the semiconductor laser element according to one embodiment of the present invention.

FIG. 6 is a graph showing the impurity concentrations of magnesium, oxygen, carbon, and silicon in the interface between a p-type optical guide layer and a p-type cladding layer in a conventional semiconductor laser element.

### BEST MODE FOR CARRYING OUT THE INVENTION

One embodiment of the present invention will be described with reference to the accompanying drawings.

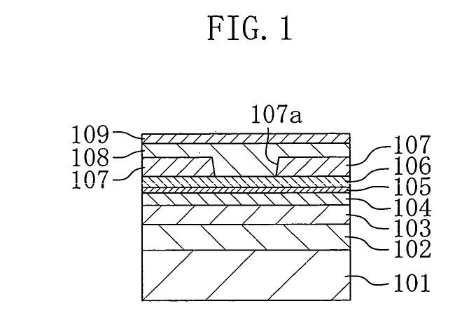

FIG. 1 shows a schematic cross-sectional structure of a semiconductor laser element which is a nitride semiconductor device according to one embodiment of the present invention.

Referring to FIG. 1, the semiconductor laser element according to this embodiment includes: an n-type GaN layer 102; an n-type cladding layer 103; an n-type optical guide layer 104; an active layer 105; and a p-type optical guide layer 106, which are sequentially formed on an n-type substrate 101 made of gallium nitride (GaN) or the like. The n-type GaN layer 102 with a thickness of 2 μm is doped with Si. The n-type cladding layer 103 with a thickness of 2 μm is made of n-type aluminum gallium nitride (AlGaN) and doped with Si. The n-type optical guide layer 104 with a thickness of 100 nm is made of n-type GaN and doped with Si. The p-type optical guide layer 106 with a thickness of 100 nm is made of a p-type GaN layer and doped with Mg.

On the p-type optical guide layer 106, an n-type current blocking layer 107 with a thickness of 100 nm is formed which is made of n-type AlGaN and has an opening 107a exposing the p-type optical guide layer 106. On the n-type current blocking layer 107 and a portion of the p-type optical guide layer 106 exposed from the opening 107a, a p-type cladding layer 108 made of p-type AlGaN is formed which is doped with Mg and whose thickness from the top surface of the p-type optical guide layer 106 is 500 nm. On the p-type cladding layer 108, a p-type contact layer 109 with a thickness of 60 nm is formed which is made of p-type GaN and doped with Mg.

Although not shown, the active layer 105 has a multiquantum well structure containing a well layer made of indium gallium nitride (InᵤGa₁₋ᵤN) or the like and a barrier layer made of indium gallium nitride (InᵥGa₁₋ᵥN) (where u and v satisfy 0≦v<u≦1). It is sufficient that the number of quantum wells in the active layer 105 is determined appropriately according to applications of the semiconductor laser element. The structure of the active layer 105 is not limited to the multiquantum well structure. Alternatively, a single quantum well structure or a bulk structure may be employed therein.

The n-type cladding layer 103 and the p-type cladding layer 108 vertically interposing the active layer 105 have the functions of: confining within the active layer 105 electrons and holes injected into the active layer 105 by a band gap thereof larger than that of the active layer 105; and confining within the active layer 105 light emitted by recombination of the confined electrons and holes. The n-type optical guide layer 104 and the p-type optical guide layer 106 formed on the surfaces of the n-type cladding layer 103 and the p-type cladding layer 108 closer to the active layer 105, respectively, have the function of facilitating confinement of the light produced by the recombination within the active layer 105.

The n-type current blocking layer 107 is provided in order to narrow a current injected through the p-type contact layer 109 and the p-type cladding layer 108 to inject it into the active layer 105. Although a detailed explanation about a formation method of the n-type current blocking layer 107 will be made later, for example, the n-type current blocking layer 107 is obtained in the manner in which a semiconductor layer made of n-type AlGaN is formed on the p-type optical guide layer 106 and then the semiconductor layer is etched to expose the p-type optical guide layer 106 in a stripe pattern. Thereafter, impurities (a deteriorated layer) induced by contaminating the exposed surface portion of the p-type optical guide layer 106 during the etching are removed to clean the n-type current blocking layer 107.

Note that in this embodiment, an ohmic n-side electrode is formed on the surface of the substrate 101 opposite to the n-type GaN layer 102, and an ohmic p-side electrode is formed on the p-type contact layer 109. However, these electrodes are omitted in this description.

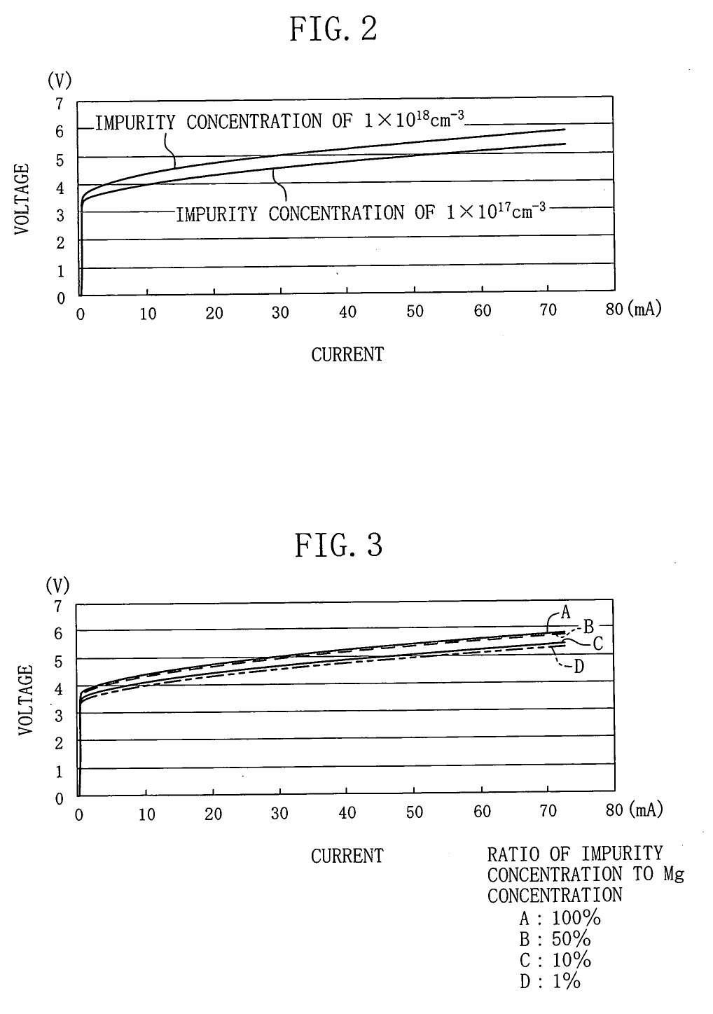

For the semiconductor laser element according to this embodiment, measurement is made of: the peak concentrations (referred hereinafter to as impurity concentrations) of oxygen (0), carbon (C), and silicon (Si) in the interface between the p-type optical guide layer 106 and the p-type cladding layer 108; and the operating voltage of the semiconductor laser element. FIG. 2 shows the result of this measurement. As a test sample, this measurement uses a semiconductor laser element which includes the p-type optical guide layer 106 containing Mg as a p-type dopant at a concentration of 1×10¹⁹ cm⁻³.

As shown in FIG. 2, in the case where the concentration of impurities due to contamination of Si and the like is 1×10¹⁷ cm⁻³, the operating voltage is lower by about 0.3 V than that in the case where the impurity concentration thereof is 1×10¹⁸ cm⁻³.

Moreover, FIG. 3 shows the result of close study of the relation between the Mg concentration in the p-type optical guide layer 106 and the impurity concentration mentioned above. Referring to FIG. 3, in the case where the ratio of the impurity concentration to the Mg concentration is 10% (the profile C), the operating voltage is obviously lower than a ratio of 100% (the profile A) and a ratio of 50% (the profile B). From this, it is found that when the concentration of impurities due to contamination is 10% or lower of the Mg concentration in the p-type optical guide layer 106, an obvious difference arises in the operating voltage.

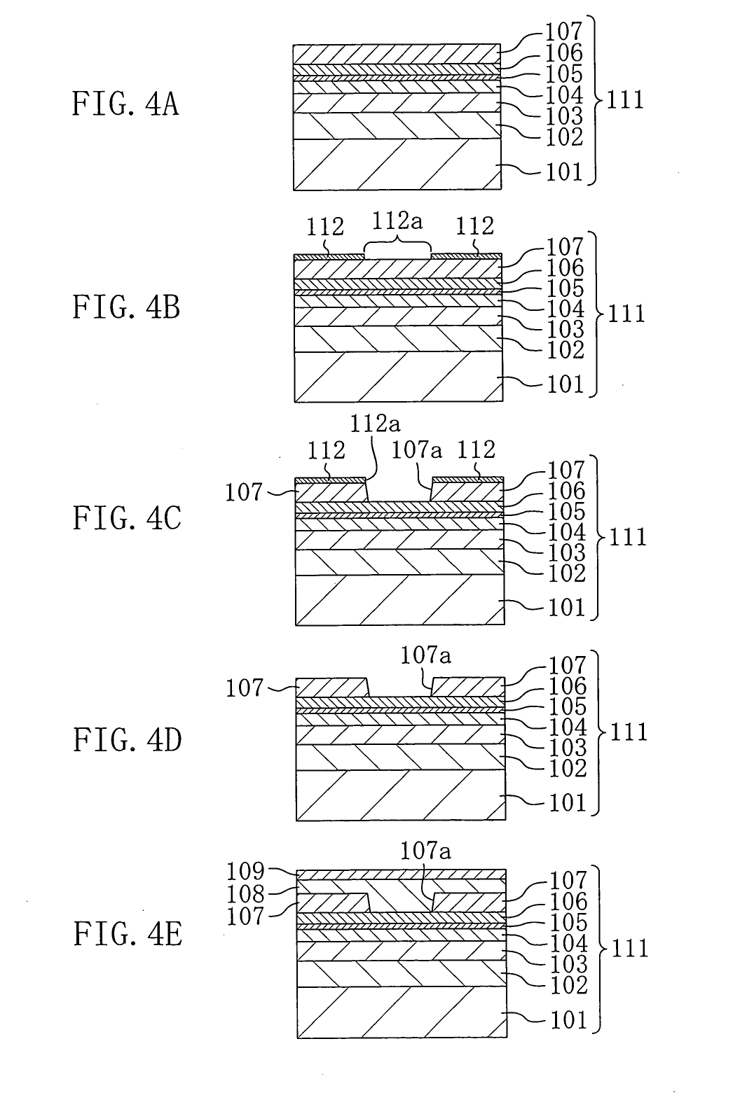

Hereinafter, a fabrication method of the semiconductor laser element constructed as mentioned above will be described with reference to FIGS. 4A to 4E.

FIGS. 4A to 4E show cross-sectional structures of the fabrication method of the semiconductor laser element according to one embodiment of the present invention in the order of its fabrication process steps.

Referring to FIG. 4A, first, by a metal-organic chemical vapor deposition (MOCVD) method or the like, the n-type GaN layer 102, the n-type cladding layer 103 of n-type AlGaN, the n-type optical guide layer 104 of n-type GaN, the active layer 105, the p-type optical guide layer 106 of p-type GaN, and the n-type current blocking layer 107 of n-type AlGaN are sequentially formed by epitaxial growth on the substrate 101 of n-type GaN. Hereinafter, the stacked structure ranging from the substrate 101 to the n-type current blocking layer 107 is referred collectively to as an epitaxial substrate 111.

As a source gas belonging to the group-III element, for example, trimethyl gallium (TMG) is employed for a gallium source, trimethyl aluminum (TMA) is employed for an aluminum source, and trimethyl indium (TMI) is employed for an indium source. Ammonia (NH₃), for example, is employed as a source of nitrogen belonging to the group-V element. Hydrogen (H₂) is employed for a bubbling gas and a carrier gas for the group-III gas source and a carrier gas for the group-V gas source. For example, silane (SiH₄) is employed for an n-type dopant, and, for example, bis(cyclopentadienyl) magnesium (Cp₂Mg) is employed for a p-type dopant.

Subsequently, the epitaxial substrate 111 is taken out of a chamber of the MOCVD system. Then, as shown in FIG. 4B, by a vacuum evaporation method, a mask film 112 made of a staked metal film of titanium (Ti) and platinum (Pt) is formed on the n-type current blocking layer 107, and then by a lithography method and an etching method, the mask film 112 is formed with an opening 112a in a stripe pattern which corresponds to a current narrowing region.

Then, as shown in FIG. 4C, the epitaxial substrate 111 is immersed in an aqueous solution of potassium hydroxide (KOH) having a solution temperature of 80° C. and a concentration of 1 mol/L. With the substrate irradiated with ultraviolet light, wet etching is performed on the portion of the n-type current blocking layer 107 exposed from the opening 112a of the mask film 112. This wet etching is performed until the p-type optical guide layer 106 underlying the n-type current blocking layer 107 is exposed, whereby the n-type current blocking layer 107 is formed with the opening 107a serving as a current narrowing region. In this process step, the mask film 112 functions as an electrode for the wet etching. In this embodiment, the wet etching is employed as an etching for forming the opening 107a through the n-type current blocking layer 107, and alternatively dry etching may be employed thereas. If dry etching is employed, a photoresist film as a substitute for the stacked metal film can be used as the mask film 112.

As shown in FIG. 4D, the mask film 112 is removed with an acid solution or the like, and then the epitaxial substrate 111 is put again into the chamber of the MOCVD system. Subsequently, while the chamber is supplied with ammonia as a nitrogen source and nitrogen (N₂) as a carrier gas for ammonia and an inert gas, the epitaxial substrate 111 is heated to 1050° C. After the substrate temperature reaches 1050° C. and the substrate temperature becomes stable, the carrier gas for ammonia is changed to hydrogen. Then, this condition is kept for five minutes. By the step of exposing the exposed surface portion of the p-type optical guide layer 106 to hydrogen gas, the deteriorated layer which is created by the wet etching in the etched surface of the p-type optical guide layer 106 and which contains impurities composed of carbon (C), oxygen (O), and silicon (Si) is removed by etching by hydrogen gas. In this step, the heating temperature is not limited to 1050° C., but it is preferably higher than the temperature at which the opening 107a is formed. In particular, a heating temperature from 1000° C. to 1100° C. inclusive can accelerate the etching by hydrogen gas without degrading the crystallinity of the p-type optical guide layer 106.

Subsequently, the carrier gas for ammonia is changed again to nitrogen, and heat treatment is performed at 950° C. for five minutes. This heat treatment in the ammonia and nitrogen atmosphere is performed under high temperatures to induce mass transport phenomena, which improves the flatness of the etched surface of the p-type optical guide layer 106 having been roughened by the wet etching and the dry etching by hydrogen gas. The temperature of this heat treatment with ammonia and nitrogen is not limited to 950° C. In particular, a heating temperature from 800° C. to 1100° C. inclusive can accelerate the mass transport phenomena.

In the impurity removal step and the mass transport step shown in FIG. 4D, the reason why ammonia serving as a nitrogen source is supplied is that nitrogen atoms constituting the crystal are prevented from dropping (vaporizing) out of the exposed surface of the epitaxial substrate 111, that is, the n-type current blocking layer 107 and the p-type optical guide layer 106. However, the gas used is not limited to ammonia, and use may be made of a compound with nitrogen radical such as dimethylhydrazine.

As shown in FIG. 4E, ammonia serving as a nitrogen source and TMA and TMG serving as a group-V element source are introduced as a supply gas, and hydrogen gas is introduced as a carrier gas for these gases. In this atmosphere, the p-type cladding layer 108 made of p-type AlGaN is epitaxially grown on the epitaxial substrate 111. Subsequently to this, supply of TMA is stopped and the p-type contact layer 109 made of p-type GaN is epitaxially grown on the p-type cladding layer 108.

Although later steps are not illustrated, for example, an n-side electrode made of a stacked film of titanium (Ti) and aluminum (Al) is formed by a vacuum evaporation method on the surface of the substrate 101 opposite to the n-type GaN layer 102. Then, for example, a p-side electrode made of a stacked film of nickel (Ni) and gold (Au) is formed on the p-type contact layer 109. In the manner described above, the semiconductor laser element is fabricated. The semiconductor laser element thus fabricated according to this embodiment has a lower operating voltage by about 0.3 V than the conventional semiconductor laser element, and thereby provides improved device characteristics.

In the fabrication method according to this embodiment, the time to etch the deteriorated layer with hydrogen gas in FIG. 4D is set at five minutes. However, the processing time varies according to the conditions such as temperature and partial pressure of hydrogen, so that the etching time is not limited to five minutes. Even if instead of hydrogen (H₂) gas, use is made of a gas capable of etching a nitride semiconductor, such as hydrogen chloride (HCl) gas, the same etching effects can be provided.

The subsequent heat treatment for inducing the mass transport phenomena in an ammonia and nitrogen atmosphere is also set to be performed for five minutes. However, the processing time varies according to the conditions such as temperature and partial pressure of ammonia, so that the treatment time is not limited to five minutes.

In addition, wet etching is used to form the opening 107a through the n-type current blocking layer 107, and alternatively dry etching may be used. Even though dry etching is used, a deteriorated layer containing impurities composed of carbon, oxygen, and silicon is created in the etched surface as in the case of the wet etching. However, the fabrication method according to this embodiment can be employed to remove the deteriorated layer easily.

Note that of the contamination-induced impurities, carbon results from an organic resin material and the like constituting, for example, a photoresist film, oxygen results from a photoresist film or an atmosphere (air), and silicon results from quartz constituting, for example, the chamber or silane used as an n-type dopant.

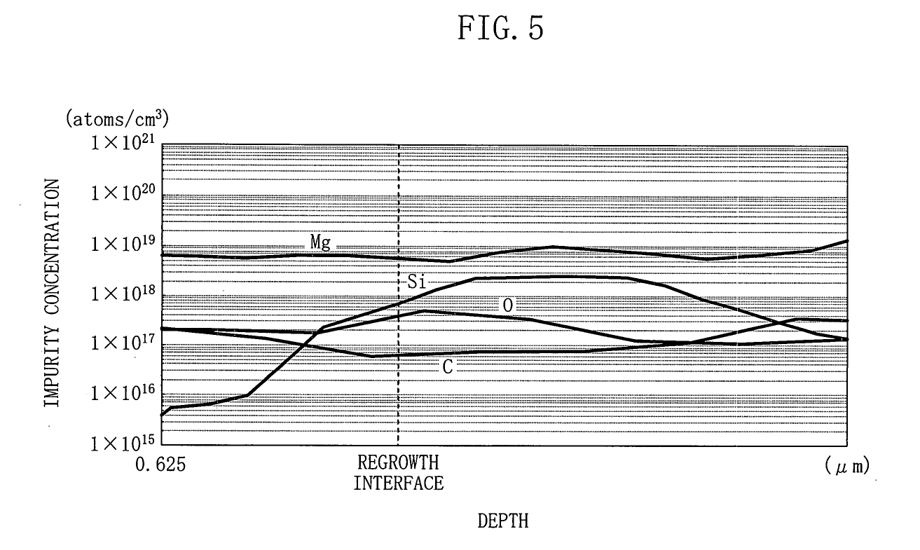

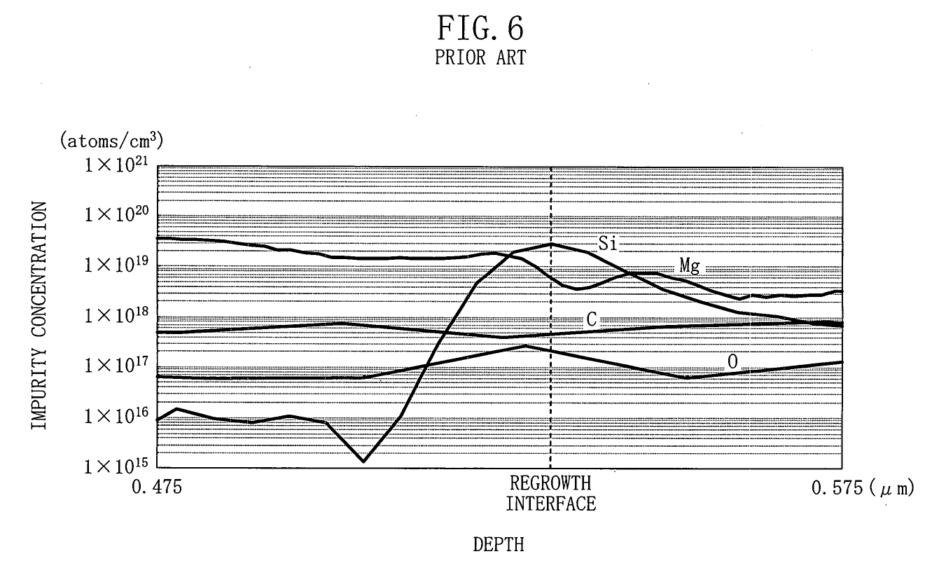

In the semiconductor laser element according to this embodiment, magnesium (Mg) serving as a p-type dopant and carbon (C), oxygen (O), and silicon (Si) serving as contamination-induced impurities are contained in the regrowth interface between the p-type optical guide layer 106 and the p-type cladding layer 108. The concentrations of these elements in the regrowth interface are measured by secondary ion mass spectrometry (SIMS), and the measurement result is shown in FIG. 5 in comparison with the conventional example in FIG. 6.

Referring to FIG. 5, for the semiconductor laser element according to this embodiment, it is shown that silicon, which has the highest concentration of contained carbon, oxygen, and silicon, has a concentration about one tenth that of magnesium serving as a p-type dopant. From this, it is found that the deteriorated layer has been removed.

In contrast to this, for the conventional semiconductor laser element shown in FIG. 6, it is shown that silicon, which has the highest concentration of contained carbon, oxygen, and silicon, has a higher concentration than that of magnesium. From this, it is found that the deteriorated layer is present.

In this embodiment, the conductivity types of one nitride semiconductor layer (the p-type optical guide layer 106) to be etched and another nitride semiconductor layer (the p-type cladding layer 108) to be regrown after the etching are both set to be p-type. However, their conductivity types may be both set to be n-type, or to be different conductivity types.

As described above, with the nitride semiconductor device and its fabrication method according to the present invention, the concentration of contamination-induced impurities created in the interface between one nitride semiconductor having the etched surface and another nitride semiconductor formed thereabove can be lowered, so that the device characteristics can be improved. Accordingly, the present invention is useful for nitride semiconductor devices such as semiconductor laser elements or light emitting diode elements.

What is claimed is:

1. A nitride semiconductor device comprising:
a first nitride semiconductor whose surface is etched; and
a second nitride semiconductor formed on the etched surface of the first nitride semiconductor,
wherein of oxygen, carbon, and silicon contained in the interface between the first and second nitride semiconductors, at least silicon has a concentration equal to or less than one tenth the dopant concentration in the first nitride semiconductor.

2. The device of claim 1,
wherein the first nitride semiconductor is a p-type nitride semiconductor.

3. The device of claim 1,
wherein the second nitride semiconductor is a p-type nitride semiconductor.

4. The device of claim 1, further comprising: a first optical guide layer of a first conductivity type; an active layer; a second optical guide layer of a second conductivity type; and a cladding layer of the second conductivity type, which are each made of a nitride semiconductor and sequentially formed on a substrate,
wherein the first nitride semiconductor is the second optical guide layer, and the second nitride semiconductor is the cladding layer.

5. The device of claim 4, further comprising a current blocking layer formed between the second optical guide layer and the cladding layer, having an opening exposing the second optical guide layer, and made of a nitride semiconductor of the first conductivity type.

6. A method for fabricating a nitride semiconductor device, comprising:
the step (a) of etching a first nitride semiconductor;
the step (b) of removing impurities in the etched surface of the first nitride semiconductor; and
the step (c) of forming a second nitride semiconductor on the etched surface of the first nitride semiconductor.

7. The method of claim 6, further comprising, after the step (b) and before the step (c), the step (d) of subjecting the etched surface of the first nitride semiconductor to heat treatment.

8. The method of claim 7,
wherein in the step (d), the heat treatment is performed in an atmosphere containing nitrogen radicals.

9. The method of claim 6,
wherein in the step (b), the impurities are removed at a higher temperature than a temperature at which the second nitride semiconductor is formed in the step (c).

10. The method of claim 6,
wherein in the step (b), the impurities are removed by etching with a gas containing at least hydrogen.

11. The method of claim 6,
wherein in the step (b), the impurities are removed by etching with a gas containing at least hydrogen chloride.

12. The method of claim 6,
wherein of oxygen, carbon, and silicon, at least silicon constitutes the impurities.

13. The method of claim 6,
wherein the first and second nitride semiconductors are p-type nitride semiconductors.

14. The method of claim 6, further comprising:
the step (e) of sequentially forming, on a substrate, a first cladding layer of a first conductivity type, a first optical guide layer of the first conductivity type, an active layer, a second optical guide layer of a second conductivity type as the first nitride semiconductor, and a current blocking layer of the first conductivity type, which are each made of a nitride semiconductor;
the step (f) of forming, by etching, an opening through the current blocking layer, the opening exposing the second optical guide layer; and
the step (g) of forming a second cladding layer of the second conductivity type on the current blocking layer with the opening formed therethrough and on a portion of the second optical guide layer exposed from the opening, the second cladding layer serving as the second nitride semiconductor,
wherein the step (b) is the step of removing impurities in the etched surface of the second optical guide layer, and
the step (c) is the step of forming the second cladding layer on the etched surface of the second optical guide layer.
